(19) United States
(12) Patent Application Publication
(10) Pub. No.: US 2025/0142860 A1
(43) Pub. Date: May 1, 2025

(54) HIGH ELECTRON MOBILITY TRANSISTOR WITH REGROWN BARRIER STRUCTURE

(71) Applicant: GlobalFoundries U.S. Inc., Malta, NY (US)

(72) Inventors: Steven J. Bentley, Menands, NY (US); Santosh Sharma, Austin, TX (US); Johnatan A. Kantarovsky, South Burlington, VT (US); Mark D. Levy, Williston, VT (US); Michael J. Zierak, Colchester, VT (US)

(21) Appl. No.: 18/385,255

(22) Filed: Oct. 30, 2023

(51) Int. Cl. H01L 29/778; H01L 29/40; H01L 29/66

(52) U.S. Cl. CPC H10D 30/47; H10D 30/015; H10D 64/112

(57) ABSTRACT

The present disclosure relates to semiconductor structures and, more particularly, to high electron mobility transistors and methods of manufacture. The structure includes: a gate structure; a first barrier layer under and adjacent to the gate structure; and a second barrier layer over the first barrier layer and which is adjacent to the gate structure.

This invention was made with government support under Contract #HQ0727790700 awarded by Defense Microelectronics Activity (DMEA). The government has certain rights in the invention.

### BACKGROUND

The present disclosure relates to semiconductor structures and, more particularly, to high electron mobility transistors and methods of manufacture.

A high-electron-mobility transistor (HEMT) is a field-effect transistor incorporating a junction between two materials with different band gaps (i.e. a heterojunction) as the channel, instead of a doped region (as is generally the case for a MOSFET). Commonly used material families are GaN or GaAs, although other materials can be used, dependent on the application of the device.

Due to the higher critical field and switching figures of merit of the GaN materials system, GaN HEMT devices typically have a higher electric-field strength than silicon MOSFETS, providing substantial performance improvements in, for example, on-resistance and breakdown voltage, while offering fast switching speed, amongst other important parameters. Since these properties result in fundamentally higher system efficiency, HEMTs may be used in diverse power management applications, such as AC-DC and DC-DC conversion in the consumer or automotive space. In RF applications, they may be used in high frequency power amplifiers, low noise amplifiers or switches in such applications as cell phones, satellite or receivers or radar equipment.

### SUMMARY

In an aspect of the disclosure, a structure comprises: a gate structure; a first barrier layer under and adjacent to the gate structure; and a second barrier layer over the first barrier layer and which is adjacent to the gate structure.

In an aspect of the disclosure, a structure comprises: a gate structure; at least one metal contact connecting to the gate structure; a channel region under the gate structure which comprises at least one semiconductor material that extends into a drain region and a source region adjacent to the gate structure, wherein the at least one semiconductor material in the drain region comprises a thicker region compared to the at least one semiconductor material under the gate structure; and a field plate over the thicker region, adjacent to the gate structure.

In an aspect of the disclosure, a method comprises: forming a gate structure; forming a first barrier layer under and adjacent to the gate structure; and forming a second barrier layer over the first barrier layer and which is adjacent to the gate structure.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a device and respective fabrication processes in accordance with aspects of the present disclosure.

FIG. 2 shows a device in accordance with additional aspects of the present disclosure.

FIG. 3 shows a device in accordance with further aspects of the present disclosure.

FIGS. 4A-4D show fabrication processes for manufacturing the HEMT device of FIG. 2 in accordance with aspects of the present disclosure.

### DETAILED DESCRIPTION

The present disclosure relates to semiconductor structures and, more particularly, to high electron mobility transistors (HEMT) and methods of manufacture. More specifically, the present disclosure relates to a GaN HEMT with a stepped-thickness barrier layer structure adjacent to the gate structure. Advantageously, the HEMT described herein provides improved electric field control in addition to lower Ron for enhanced performance and reliability.

In more specific embodiments, the structure comprises a GaN HEMT with a gate structure, source/drain regions adjacent to the gate structure and an optional field plate. A barrier layer, e.g., AlGaN, is epitaxially grown adjacent to the gate structure, and has a substantially step change in thickness adjacent to the gate. In embodiments, the change can be a curve or tapered profile or a stepped feature. The thicker region may be symmetrically spaced from the gate structure. In some embodiments, the gate structure may include a p-doped GaN layer in addition to one or more gate metals. The barrier layer may be symmetrically self-aligned to the gate structure and, e.g., separated from the gate structure by equal distances on both sides. The thicker region of the barrier layer is spaced away from the gate structure and may have a different composition to the barrier layer under the gate structure.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

In addition, the present disclosure utilizes epitaxy processes as is known in the art. Epitaxy refers to a type of crystal growth or material deposition in which new crystalline layers are formed with one or more well-defined orientations with respect to the crystalline seed layer. For most epitaxial growths, the new layer is usually crystalline and each crystallographic domain of the overlayer has a well-defined orientation relative to the substrate crystal structure. Epitaxy can involve single-crystal structures. An epitaxial layer can be doped during deposition by adding a flow of impurities, such as arsine, phosphine, or via the use of metal-organic precursors. Dopants in the source may diffuse into the epitaxial layer. The concentration of impurity in the gas/vapor phase determines its concentration in the deposited film. Additionally, the high temperatures at which epitaxy is performed may allow dopants to diffuse into the growing layer from other layers in the wafer (out-diffusion).

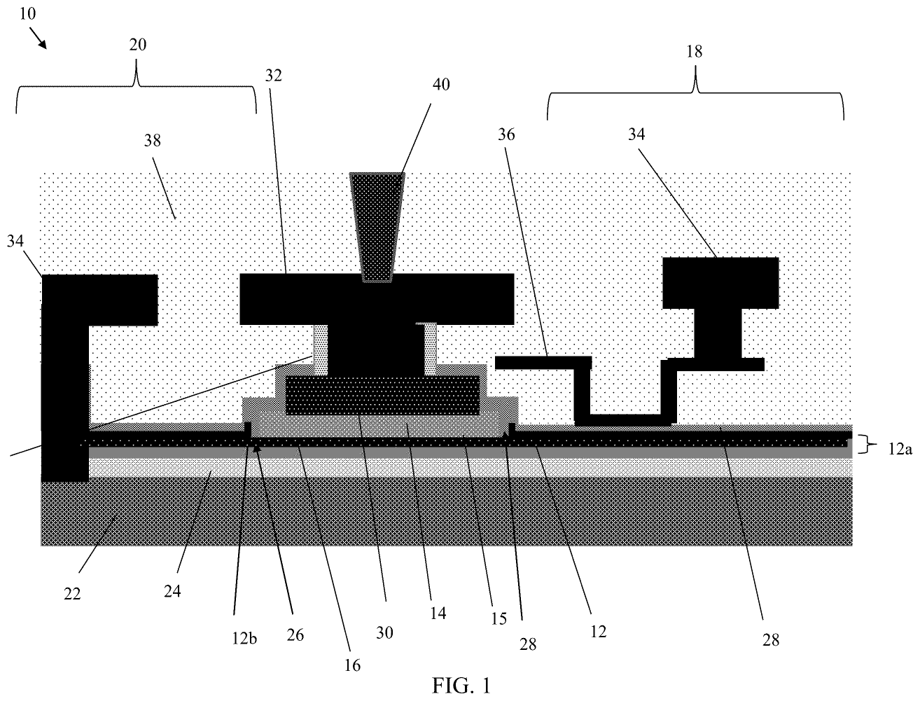

FIG. 1 shows a device and respective fabrication processes in accordance with aspects of the present disclosure. In embodiments, the device 10 may be a HEMT comprising a raised barrier layer 12 self-aligned to and surrounding a gate structure 14 within a drain region 18 and, optionally, within a source region 20. In embodiments, the raised barrier layer 12 may be formed over a barrier layer 16. The combination of the barrier layers 12, 16 adjacent to the gate structure 14 in the drain region 18 may form a thicker region 12a compared to only the barrier layer 16 under the gate structure 14. The thicker region 12a may act to reduce channel resistance between the gate structure 14 and the drain region 18. For example, the increased volume of semiconductor material at the thicker region 12a allows an increase in carrier concentration of 2DEG (e.g., 2-dimensional electron gas) in the channel region of the device under the thicker region 12a, effectively reducing the resistance of the channel layer 15.

In more specific embodiments, the device 10 of FIG. 1 includes a semiconductor substrate 22 with a buffer layer 24 over the semiconductor substrate 22, a channel layer 15 and the barrier layers 12, 16 over the buffer layer 24. The gate structure 14 may be formed over the barrier layer 16 and between islands of the barrier layer 12. In embodiments, the barrier layer 12 may be a self-aligned barrier layer formed over the barrier layer 16 outside of the gate structure 14 (e.g., adjacent to the gate structure 14 in the drain region 18 and, optionally, the source region 20); whereas the barrier layer 16 is both adjacent to and underneath the gate structure 14. In this way, the combination of the barrier layers 12, 16 forms a thicker region 12a in the drain region 18 and, optionally, the source region 20 of the device 10.

In embodiments, the semiconductor substrate 22 may be, e.g., Si, with a single crystalline orientation. For example, in preferred embodiments, the semiconductor substrate 22 comprises p-type Si material with a suitable crystal orientation, e.g., (111). In alternative embodiments, the semiconductor substrate 22 may any suitable material including, but not limited to, SiC, SiGe, SiGeC, GaAs, InAs, InP, Sapphire and other III/V or II/VI compound semiconductors, including engineered substrates such as SOI or QST. The buffer layer 24 may be any semiconductor material that acts as a buffer material in a HEMT as is known in the art. For example, the buffer layer 24 may be GaN, AlGaN, or any combination thereof. The gate structure 14 may include one or more layers of GaN or AlGaN, which may be partially p- or n-doped, and may include one or more metallic layers.

In embodiments, the barrier layer 12 may be an epitaxially grown semiconductor material on the barrier layer 16. In embodiments, the barrier layers 12, 16 may both be AlGaN. In alternative embodiments, the barrier layers 12, 16 may be different materials or the same material with different material compositions, e.g., alloy compositions. For example, the barrier layer 16 may be AlₓGa₁₋ₓN and the barrier layer 12 may be Al_{y}Ga_{1-y}N, InₓAl₁₋ₓN, AlN, etc., where x and y comprise the mole fraction of the respective ternary. The thicker region 12a may, for example, have a different Al concentration near the top surface than near a bottom surface, or maybe graded in composition. The AlGaN/GaN layers, e.g., channel layer 15 and barrier layers 12, 16, may result in a conducting 2DEG channel for the HEMT device 10.

The barrier layer 16 may be positioned symmetrically or asymmetrically about the gate structure 14, e.g., adjacent to the gate structure 14 in the drain region 18 and, optionally, in the source region 20. In this way, the combination of the barrier layers 12, 16 in the drain region 18 form a thicker region 12a than the barrier layer 16 under the gate structure 14. In embodiments, the thicker region 12a may also be partially or fully under a field plate 36. The field plate 36 may include steps or variations in the dielectric thickness between it and the dielectric material 28.

In embodiments, the thicker region 12a may be twice as thick as the barrier layer 16, alone, under the gate structure 14; although other dimensions are also contemplated herein depending on the device specifications and desired performance. For example, the barrier layer 16 may be 2 nm to 25 nm, in thickness, scaling to a particular device application; whereas the thicker region 12a, e.g., combination of the barrier layers 12, 16, may range from about 5% to 100% greater in thickness than the barrier layer 16, alone. As already disclosed herein, the thicker region 12a may act to reduce channel resistance between the gate structure 14 and the drain region 18, i.e., allows an increase in carrier concentration of 2DEG which effectively reduces the resistance of the channel layer 15.

In further embodiments, the barrier layer 12 may be separated or remote from the gate structure 14 by a gap 26 filled with a dielectric material 28. In embodiments, the gap 26 may be symmetrical or asymmetrical positioned about the gate structure 24. For example, the gap 26 between the barrier layer 12, e.g., AlGaN, and the gate structure 14, e.g., pGaN and metal, can be modulated by use of a lithographic mask during a spacer etch process. The mask can also allow placement of edge 12b of the barrier layer 12 at an arbitrary distance away from the gate structure 14, while another side remains self-aligned to the gate structure 14. In embodiments, this could be done on either the source or drain side of the gate, or in the third dimension (in the device width direction). Further, such patterning could also allow “islands” of thicker barrier to be formed arbitrarily over the surface of barrier 16.

In embodiments, the dielectric material 28 may be provided over the barrier layer 12 and in the gap 26 between the barrier layer 12 and the gate structure 14. The dielectric material 28 may also be provided over the gate structure 14 and a gate metal 30 connecting to and over the gate structure 14. The dielectric material 28 may be aluminum oxide (e.g., Al₂O₃) or silicon oxide (e.g., SiO₂) or silicon nitride (e.g., Si₃N₄) or combinations thereof, and may be deposited by, for example, an atomic layer deposition (ALD), physical vapor deposition (PVD), or chemical vapor deposition (CVD) process.

The gate metal 30 may be formed in direct contact with the gate structure 14 at a first level of the device. Additional gate metal 32 may be formed over and in direct contact with the gate metal 30. The gate metal 32 may include spacers 33 on its vertical sidewalls, which may isolate the gate metal 32 from the field plate 36. A metal material 34 may also be formed to the source region 20 and drain region 18 (e.g., source contact and drain contact), with the drain region 18 including the field plate 36 partially or completely over the thicker region 12a. In embodiments, the gate metals 30, 32, and metal material 34 may be any appropriate conductive material, e.g., tungsten or aluminum with a TiN or TaN liner. The field plate 36 may be TiN, for example. The spacers 33 may be any oxide material, nitride material or combinations thereof.

The field plate 36 may be formed over and in contact with the dielectric material 28, extending over the thicker region 12a of the combination of barrier layers 12, 16. Moreover, in embodiments, the field plate 26 may be electrically connected to the source contact 34 and potentially another field plate may be connected to the drain region 20. In embodiments, the field plate structure 36 (which may be part of a larger multi-step metallic field plate structure) may have steps at multiple heights spaced vertically from the surface of the barrier layers 12a. In embodiments, the field plate structure 36 may connect to the same metals that comprise the source/drain ohmic metals (e.g., metal structure 34), and/or gate metal 32 in order to form this larger multi-step metallic structure. In embodiments, the multi-step metallic field plate structure may straddle the dual thickness barrier layers 12, 16, e.g., AlGaN.

The gate metals 30, 32, metal material 34, via interconnect structures 40 and field plate 36 may be formed within different layers of the interlevel dielectric 38 using conventional lithography, etching and deposition methods as is known in the art. By way of example, a resist formed over the insulator material 38 is exposed to energy (light) and developed utilizing a conventional resist developer to form a pattern (opening). An etching process with a selective chemistry, e.g., reactive ion etching (RIE), will be used to transfer the pattern from the patterned photoresist layer to the insulator material 38 to form one or more trenches in the insulator material 38 through the openings of the resist. Following the resist removal by a conventional oxygen ashing process or other known stripants, conductive material can be deposited by any conventional deposition processes, e.g., chemical vapor deposition (CVD) processes. Any residual material on the surface of the insulator material 38 can be removed by conventional chemical mechanical polishing (CMP) processes. The field plate 36, gate metal 32 or Ohmic metal 34 may be similarly patterned to include metal material on the insulator material 38 at certain wiring levels.

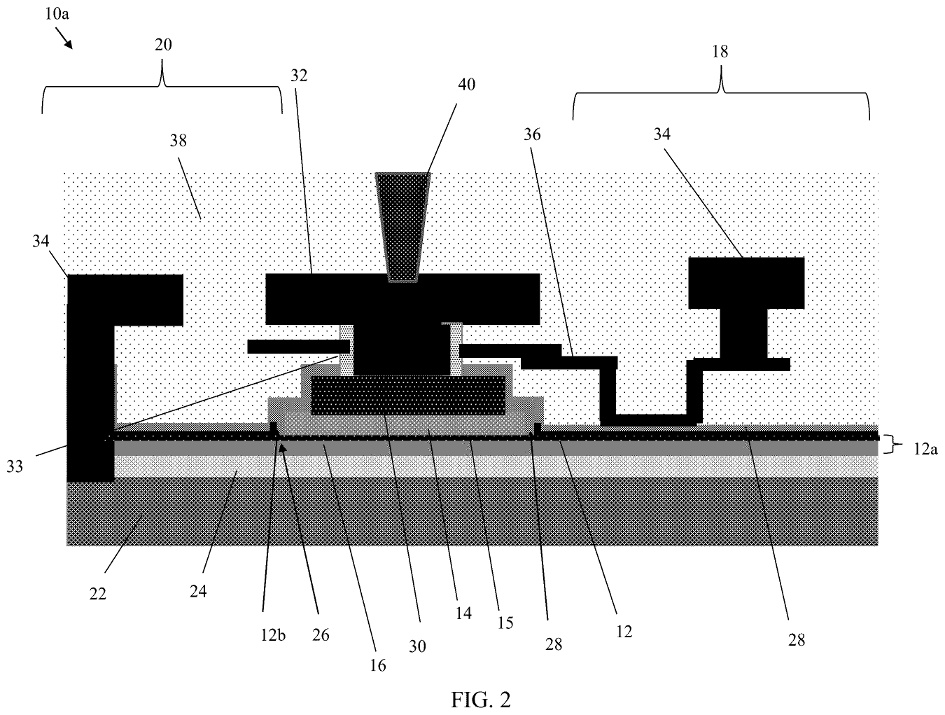

FIG. 2 shows a device in accordance with additional aspects of the present disclosure. In embodiments, the device 10a may be a HEMT comprising a self-aligned field plate 36 which surrounds the vertical portion of the metal layer 32 such that field plate metal is present on both the source and drain sides of the gate, e.g., self-aligned field plate. The spacers 33 will isolate the gate metal 32 from the field plate 36. The device 10a also includes the thicker region 12a adjacent to the gate structure 14, with a gap 26 filled with insulator material 28 between the barrier layer 12 and the gate structure 14. The remaining features of the device 10a are similar to the device 10 of FIG. 1.

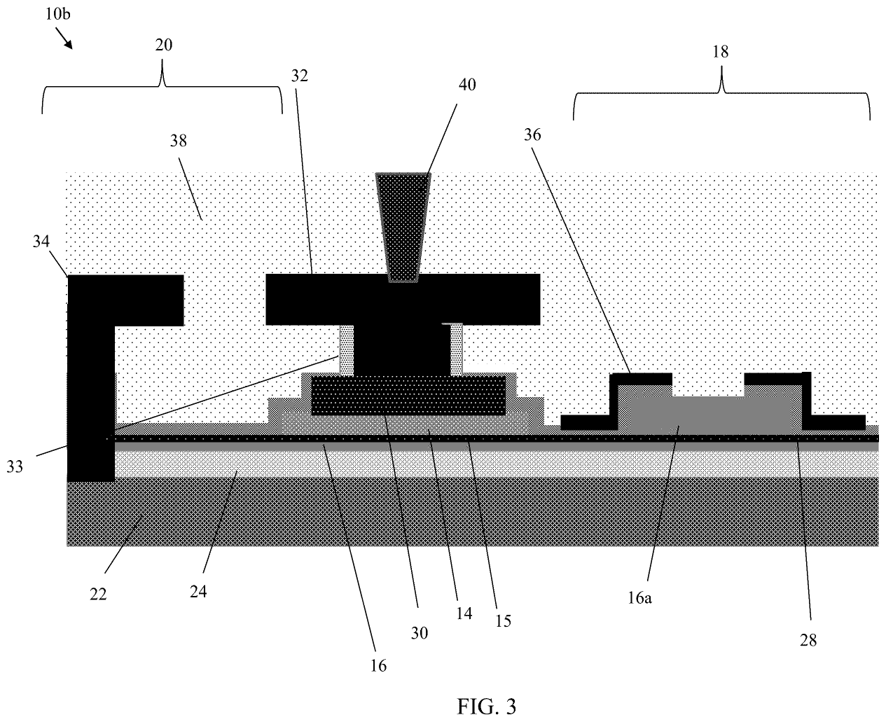

FIG. 3 shows a device in accordance with further aspects of the present disclosure. In embodiments, the device 10b may be a HEMT comprising a field plate 36 adjacent to or near the gate structure 14, at a same device level. The field plate 36 also straddles or extends onto the thicker region 12a adjacent to the gate structure 14. In this configuration, the field plate 36 is not self-aligned, but does extend over the stepped portion 16a, e.g., thicker regions, comprising the barrier layer 16. In other configurations, the field plate may be self-aligned to the gate as shown in FIG. 2, or may have similar steps or electrical connections in some portions as shown in FIG. 1. The remaining features of the device 10a are similar to the device 10 of FIG. 1.

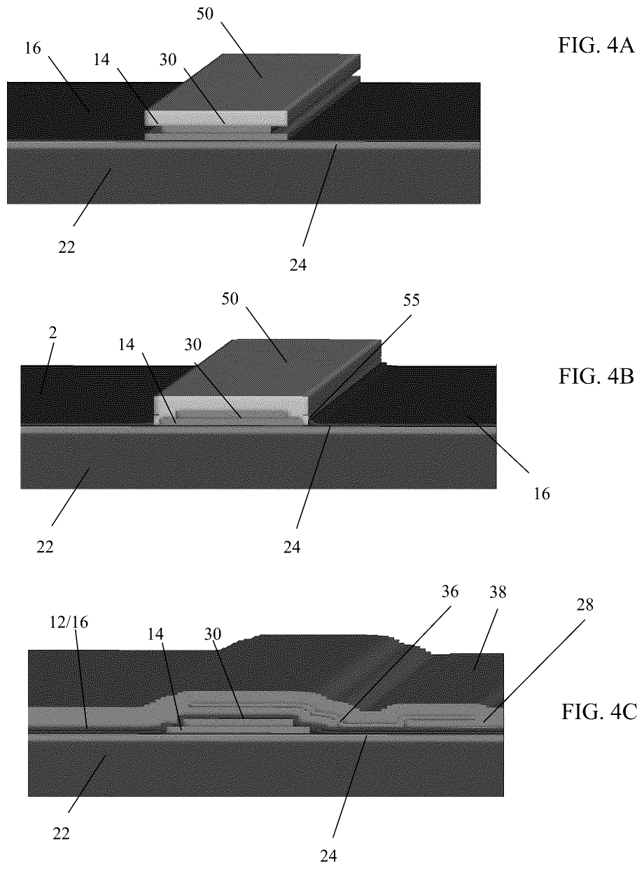

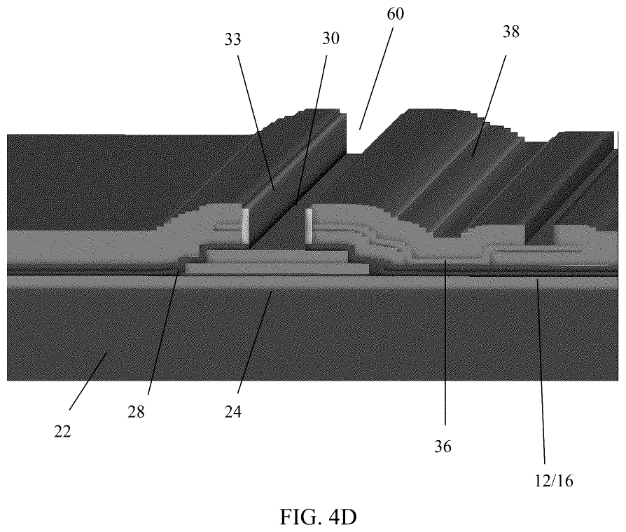

FIGS. 4A-4D show fabrication processes for manufacturing the HEMT device of FIG. 2, for example. Specifically, FIG. 4A shows the buffer layer 24 formed over the semiconductor substrate 22 and the barrier layer 16 formed over the buffer layer 24. In embodiments, the buffer layer 24 and the barrier layer 16 may be formed by conventional deposition processes including, for example, an epitaxial growth process.

Still referring to FIG. 4A, the gate structure 14 is formed over the barrier layer 16. The gate structure 14 can be formed by an in-situ doped epitaxial growth process, e.g., p-doped GaN, followed by a patterning process. The gate metal 30 may be formed over the gate structure 14 by a conventional deposition process, e.g., chemical vapor deposition, followed by a conventional patterning process using hardmask 50, which may, for example, be a dielectric material. In other embodiments, the gate metal 30 may not be present, and may be deposited at a later stage. In embodiments, the patterning processes may be conventional lithography and etching processes (e.g., RIE or wet anisotropic or isotropic etches).

In FIG. 4B, sidewall spacers 55 are formed on the sides of the gate structure 14. In embodiments, the sidewalls 55 may be formed by a conventional deposition process, e.g., CVD or plasma enhanced CVD (PECVD) as examples. The sidewalls 55 may comprise a sacrificial nitride or oxide material, as an example. Following the deposition process, an etching process can be performed to remove any excessive sidewall material on the barrier layer 16.

In FIG. 4C, the barrier layer 12 may be deposited over the barrier layer 12. In embodiments, the barrier layer 12 may be epitaxially grown over the barrier layer 16, with the sidewall spacers 55 preventing contact between the barrier layer 12 and the gate structure 16. Thereafter, the hardmask and sidewall spacers 55 can be removed to form the gap, followed by the deposition of the dielectric material 28 in the gap and over the barrier layer 12, the gate metal 30 and the gate structure 14. The dielectric material 28 may be AlO₂ or SiO₂ or nitride or combinations thereof, deposited by any known deposition method, e.g., ALD, CVD, PVD, etc.

Still referring to FIG. 4C, the interlevel dielectric material 38 may be deposited on the dielectric material 28. A trench may be formed in the interlevel dielectric material 38 using conventional lithography and etching process, followed by field plate formation. The field plate 36 may be formed by the deposition of a metal material which lines the trench and a surface of the interlevel dielectric material 38. The metal material can be patterned, e.g., etched, to form the field plate 36. In the embodiment of FIG. 2, for example, the field plate 36 can be patterned to extend over the gate structure 14, or it may be patterned such that it does not extend over the gate structure 14. In still other embodiments, the field plate 36 may be deposited at a later stage in the flow. Another layer of interlevel dielectric material 38 may be deposited over the field plate 36. The interlevel dielectric materials 38 may be formed by a conventional blanket deposition process, e.g., CVD.

FIG. 4D shows a self-aligned field plate gate process. For example, a trench 60 is formed through the interlevel dielectric material 38, field plate 36 (for the embodiment of FIG. 2) and the dielectric material 28, which exposes the gate metal 30. The spacers 33 may be formed by the deposition of a sidewall material, e.g., nitride, to line the trench 60 and portions of the interlevel dielectric material 28. The sidewall material may be deposited by a conventional deposition method, e.g., CVD, followed by an anisotropic etching process to remove the sidewall material from the bottom of the trench 60 and the interlevel dielectric material 38. The processes may continue with respect to the formation of the metal layers, e.g., gate metal 32, metal material 34, and via interconnect structures 40 as noted with respect to FIG. 1.

The HEMT can be utilized as a single device in discrete applications, may be combined in a single package with several other devices of the same or varying types via co-packaging or multi-chip 3D integration techniques, or may be combined with several other devices in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things. Moreover, GaN devices are increasingly being employed in SoC designs where multiple GaN HEMTs are formed on a single substrate.

The method(s) as described above is used in the fabrication of discrete device or integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes discrete or integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a gate structure;
a first barrier layer under and adjacent to the gate structure; and
a second barrier layer over the first barrier layer and which is adjacent to the gate structure.

2. The structure of claim 1, wherein the first barrier layer and the second barrier layer adjacent to the gate structure comprise a thicker region compared to the first barrier layer under the gate structure.

3. The structure of claim 2, further comprising a field plate above the thicker region.

4. The structure of claim 3, further comprising a gate metal connecting to the gate structure.

5. The structure of claim 4, wherein the field plate surrounds the gate metal and is isolated from the gate structure by a spacer on vertical sidewalls of the gate metal.

6. The structure of claim 3, wherein the field plate is adjacent to the gate structure on a same device level and further straddles over the thicker region.

7. The structure of claim 1, wherein the second barrier layer is symmetrically positioned about the gate structure.

8. The structure of claim 1, wherein the second barrier layer is asymmetrically positioned about the gate structure.

9. The structure of claim 1, wherein the first barrier layer and the second barrier layer comprise a same material.

10. The structure of claim 1, wherein the first barrier layer and the second barrier layer comprise a same material with different alloy compositions.

11. The structure of claim 1, wherein the first barrier layer and the second barrier layer comprise different materials.

12. The structure of claim 1, wherein the second barrier layer is spaced away from the gate structure by a gap structure comprising an insulator material.

13. A structure comprising:
a gate structure;
at least one metal contact connecting to the gate structure;
a channel region under the gate structure which comprises at least one semiconductor material that extends into a drain region and a source region adjacent to the gate structure, wherein the at least one semiconductor material in the drain region comprises a thicker region compared to the at least one semiconductor material under the gate structure; and
a field plate over the thicker region, adjacent to the gate structure.

14. The structure of claim 13, wherein the at least one semiconductor material comprises a first semiconductor under the gate structure and a combination of the first semiconductor material and a second semiconductor material in the drain region, wherein the combination of the first semiconductor material and the second semiconductor material comprises the thicker region.

15. The structure of claim 14, wherein the first semiconductor material and the second semiconductor material comprise AlGaN.

16. The structure of claim 14, wherein the second semiconductor material is symmetrically positioned about the gate structure.

17. The structure of claim 14, wherein the first semiconductor material and the second semiconductor material comprise a same material with different material compositions.

18. The structure of claim 14, wherein the first semiconductor material and the second semiconductor material comprise different materials.

19. The structure of claim 13, wherein the second semiconductor material is separated from the gate structure by a gap structure comprising an insulator material.

20. A method comprising:
forming a gate structure;
forming a first barrier layer under and adjacent to the gate structure; and
forming a second barrier layer over the first barrier layer and which is adjacent to the gate structure.
